(19) United States
(12) Patent Application Publication
(10) Pub. No.: US 2019/0353882 A1
(43) Pub. Date: Nov. 21, 2019

(54) SOLAR CONCENTRATOR APPARATUS AND SOLAR COLLECTOR ARRAY

(71) Applicant: MORGAN SOLAR INC., Toronto (CA)

(72) Inventors: John Paul MORGAN, Toronto (CA); Brett BARNES, Toronto (CA); Stephen CAELERS, Toronto (CA)

(21) Appl. No.: 16/478,028

(22) PCT Filed: Jan. 25, 2017
(86) PCT No.: PCT/IB2017/050385

§ 371 Date: Jul. 15, 2019

(51) Int. Cl. G02B 19/00; H01L 31/054

(52) U.S. Cl. CPC G02B 19/0028; H01L 31/0547; H01L 31/0543; G02B 19/0042

(57) ABSTRACT

A solar concentrator apparatus including at least one refracting component comprising a plurality of refracting elements; a receiving layer including at least one solar energy collector and being adjacent and optically connected to the refracting component; at least one reflecting component adjacent and optically connected to the receiving layer, the reflecting component being disposed opposite the at least one refracting component, the reflecting component comprising a plurality of reflecting elements, each one of the reflecting elements being associated with a corresponding one of the refracting elements, each one of the reflecting elements comprising first and second reflecting surfaces; wherein the refracting elements are positioned to refract light towards the at least one reflecting component, each reflecting element receiving refracted light from its refracting element, the at least one solar energy collector receiving reflected light from each of reflecting elements immediately subsequent reflection by the second reflecting surface.

### TECHNICAL FIELD

The present technology relates generally to light panels and particularly to a concentrated photovoltaic panel.

### BACKGROUND

In the field of solar energy, conventional photovoltaic panels are used to generate electricity from sunlight. Conventional photovoltaic panels consist of arrays of photovoltaic cells, with each cell consisting of a semiconductor (e.g. monocrystalline silicon or polycrystalline silicon) substrate. The photovoltaic cells collect the solar energy and convert the solar energy into an electric current, where the power output from such conventional photovoltaic panels is a direct function of the total substrate area of the array. As a result, sizeable arrays of large, expensive semiconductor substrates are typically needed to generate sufficient electrical output.

There has been research and product development for many alternative methods of harvesting the energy from the sun to produce electric energy. In the field of concentrated photovoltaics (CPV), the need for large semiconductor substrates can be substantially reduced by concentrating solar light with optical elements, such as lenses and reflectors. The optical elements collect light over a wide surface area and direct the light towards a photovoltaic cell of substantially smaller surface area. The optical elements can be made of inexpensive materials such as glass or polymers to achieve competitive prices, and the photovoltaic cell is typically a high efficiency multi-junction cell for improving efficiency.

U.S. Patent Application Publication No. 2008/0271776 A1 to Morgan describes a solar energy system that uses a light-guide solar panel (LGSP) to trap light inside a transparent panel and propagate the light to one of the panel edges for harvesting by a solar energy collector such as a photovoltaic cell. This technology eliminates the depth requirements inherent in traditional concentrated photovoltaic solar energy systems.

Improvements are generally desired. It is therefore an object at least to provide a novel concentrated photovoltaic panel.

### SUMMARY

It is an object of the present to ameliorate at least some of the inconveniences present in the prior art.

In one aspect, there is provided a solar concentrator apparatus comprising: at least one refracting component, the at least one refracting component comprising a plurality of refracting elements; a receiving layer, the receiving layer comprising at least one solar energy collector, the receiving layer being adjacent and optically connected to the refracting component; at least one reflecting component, the at least one reflecting component being adjacent and optically connected to the receiving layer, the at least one reflecting component comprising a plurality of reflecting elements, each of the plurality of reflecting elements being associated with one of the plurality of refracting elements, each of the plurality of reflecting elements comprising a first reflecting surface and a second reflecting surface; wherein light impinging on the at least one refracting component can be refracted by the refracting elements and transmitted through the receiving layer to the at least one reflecting component, where the first reflecting surfaces of the associated reflecting elements can reflect the light towards the second reflecting surfaces; and wherein the second reflecting surfaces can reflect the light directly towards the solar energy collector.

In one aspect, the plurality of first reflecting surfaces and the plurality of second reflecting surfaces can operate by total internal reflection; in another aspect, each of the plurality of first reflecting surfaces and the plurality of second reflecting surfaces may have mirrored coatings applied thereon.

The at least one refracting component, the receiving layer, and the at least one reflecting component are generally planar. Furthermore, each of the plurality of refracting elements can have a spherical, parabolic, elliptical, or free-form shape. Each of the plurality of first reflecting surfaces may also have a spherical, parabolic, elliptical, or free-form shape. Each of the plurality of second reflecting surfaces may also be spherical, parabolic, elliptical, or free-form.

The solar concentrator apparatus may further comprise a first bonding layer disposed between the receiving layer and the at least one reflecting component; and a second bonding layer disposed between the receiving layer and the at least one refracting component. The first and second bonding layers can be made of a flexible or compliant material such that they can be stretched when there is thermal expansion to one of the refracting component or the reflecting component.

In the present technology, light incident on each of the plurality of first reflecting surfaces can be directed to the second reflecting surface of the same reflecting element by a single reflection. The light incident on each of the plurality of second reflecting surfaces can be directed to the solar energy collector, also by a single reflection.

In one aspect, the receiving layer comprises a first transparent sheet having an electric circuit attached thereon; and a second transparent sheet spaced from and parallel to the first transparent sheet. The one or more solar energy collectors may be disposed between the first and second transparent sheets. The at least one solar energy collector can be a photovoltaic cell; and the electric energy generated by the at least one photovoltaic cell, can be transmitted through the electric circuit.

The receiving layer may further comprise a light transmissive material between the first transparent sheet and the second transparent sheet. This light transmissive material can be a gas such as air, an optical immersion liquid, an optical gel, or any index matched, light transmissive or transparent material, or an encapsulating polymer such as silicone. In some aspects of the present technology, the light transmissive material may act as an adhesive between the first and second transparent sheets. The light transmissive material can be an electrical encapsulant for the electrical circuit.

The electric circuit can be positioned to avoid the light path within the solar concentrator apparatus.

The solar concentrator apparatus may include a plurality of refracting components and a plurality of corresponding reflecting components, such that there is a one to one relationship between them, and the solar concentrator apparatus is in the form of an array.

If the solar concentrator apparatus is in the form of an array, it comprises a plurality of refracting components, a plurality of reflecting components, and a plurality of solar energy collectors. The plurality of refracting components may comprise a plurality of refracting elements. The receiving layer may comprise the plurality of solar energy collectors. The receiving layer may be adjacent and optically connected to the plurality of refracting components. The reflecting components may be adjacent and optically connected to the receiving layer, and the reflecting components may comprise a plurality of reflecting elements. Each of the plurality of reflecting elements may be associated with one of the plurality of refracting elements. The plurality of reflecting elements may comprise a plurality of first reflecting surfaces and second reflecting surfaces.

Light impinging on the at least one refracting component is refracted by the refracting elements and transmitted through the receiving layer to the at least one reflecting component, where the first reflecting surfaces of the associated reflecting elements reflect the light towards the second reflecting surfaces; and wherein the second reflecting surface reflects the light towards the solar energy collector. The refracting components, the solar energy collectors and the reflecting components are arranged such that there is a relationship between one refracting component, one reflecting component and one solar energy collector of the receiving layer.

In the array of solar collector apparatuses, the solar collector apparatuses may be arranged in a substantially hexagonal grid.

According to one aspect of the present technology, there is provided a solar concentrator apparatus comprising at least one refracting component, the at least one refracting component comprising a plurality of refracting elements; a receiving layer comprising at least one solar energy collector, the receiving layer being adjacent and optically connected to the at least one refracting component; at least one reflecting component adjacent and optically connected to the receiving layer, the at least one reflecting component being disposed on a side of the receiving layer opposite the at least one refracting component, the at least one reflecting component comprising a plurality of reflecting elements, each one of the plurality of reflecting elements being associated with a corresponding one of the plurality of refracting elements, each one of the plurality of reflecting elements comprising a first reflecting surface and a second reflecting surface; wherein the plurality of refracting elements are positioned to refract light impinging thereon towards the at least one reflecting component, each one of the plurality of reflecting elements receiving refracted light from its corresponding one of the plurality of refracting elements, the at least one solar energy collector receiving reflected light from each one of the plurality of reflecting elements immediately subsequent reflection by the second reflecting surface.

In some embodiments, the plurality of reflecting elements operate by total internal reflection.

In some embodiments, each of the at least one refracting component, the receiving layer, and the at least one reflecting component include at least one planar surface.

In some embodiments, the solar concentrator apparatus further comprises an elastomeric layer disposed between at least a portion of the receiving layer and the at least one refracting component.

In some embodiments, the solar concentrator apparatus further comprises an elastomeric layer disposed between the receiving layer and the at least one reflecting component.

In some embodiments, for each one of the plurality of reflecting elements, the first reflecting surface is positioned to reflect light incident thereon towards the second reflecting surface, the incident light undergoing a single reflection between the corresponding one of the plurality of refracting elements and the second reflecting surface.

In some embodiments, wherein for each one of the plurality of reflecting elements, the second reflecting surface is positioned to reflect light incident thereon towards the at least one solar energy collector, the incident light undergoing a single reflection between the first reflecting surface and the at least one solar energy collector.

In some embodiments, the receiving layer comprises a rigid transparent sheet having an electrical circuit attached thereto, the at least one solar energy collector and the at least one refracting component are disposed on a same side of the rigid transparent sheet.

In some embodiments, the at least one refracting component defines a hole at its center.

In some embodiments, the at least one solar energy collector is disposed within the hole.

In some embodiments, the at least one solar energy collector is at least one photovoltaic cell.

In some embodiments, the receiving layer comprises a first transparent sheet having an electrical circuit attached thereto; a second transparent sheet operatively connected and parallel to the first transparent sheet; and wherein the at least one solar energy collector is disposed between the first and second transparent sheets, the at least one solar energy collector is at least one photovoltaic cell; and electrical energy generated by the at least one photovoltaic cell is transmitted through the electrical circuit.

In some embodiments, the receiving layer further comprises a light transmissive material disposed between the first transparent sheet and the second transparent sheet.

In some embodiments, the light transmissive material acts as an adhesive between the first transparent sheet and the second transparent sheet.

In some embodiments, the electrical circuit is positioned to avoid a light path within the solar concentrator apparatus.

According to another aspect of the present technology, there is provided a solar collector array, comprising a plurality of solar collector apparatuses as described above.

In some embodiments, the solar collector apparatuses are arranged in a substantially hexagonal grid.

According to yet another aspect of the present technology, there is provided an array of solar concentrator apparatuses comprising a plurality of refracting components, each refracting component further comprising a plurality of refracting elements; a receiving layer, the receiving layer comprising a plurality of solar energy collectors, the receiving layer being adjacent and optically connected to the plurality of refracting components; a plurality of reflecting components, the plurality of reflecting components being adjacent and optically connected to the receiving layer, each one of the plurality of reflecting component being associated with a corresponding one of the plurality of refracting components, each one of the plurality of reflecting component comprising a plurality of reflecting elements, each one of the plurality of refracting elements being associated with a corresponding one of the plurality of reflecting elements, each of the plurality of reflecting elements comprising a first reflecting surface and a second reflecting surface; wherein each one of the plurality of refracting elements is positioned to refract light impinging thereon towards the corresponding one of the plurality of reflecting elements, for each one of the plurality of reflecting elements, the first reflecting surface reflects light towards the second reflecting surface, and each one of the plurality of reflecting elements receives refracted light from its corresponding one of the plurality of refracting elements, the at least one solar energy collector receiving reflected light from each one of the plurality of reflecting elements immediately subsequent reflection by the second reflecting surface.

In some embodiments, the plurality of refracting components, the plurality of solar energy collectors and the plurality reflecting components are arranged such that there is a one to one relationship between each one of the plurality of refracting components, a corresponding one of the plurality of reflecting components and a corresponding one of the plurality of solar energy collectors.

Embodiments of the present technology each have at least one of the above-mentioned object and/or aspects, but do not necessarily have all of them. It should be understood that some aspects of the present technology that have resulted from attempting to attain the above-mentioned object may not satisfy this object and/or may satisfy other objects not specifically recited herein.

Additional and/or alternative features, aspects and advantages of embodiments of the present technology will become apparent from the following description, the accompanying drawings and the appended claims.

### BRIEF DESCRIPTION OF THE DRAWINGS

Embodiments will now be described more fully with reference to the accompanying drawings in which:

FIG. 1A is a cross-sectional view of a solar concentrator apparatus;

FIG. 1B is a top isometric view of a solar concentrator apparatus;

FIG. 1C is a zoomed in view of the embodiment of FIG. 1B;

FIG. 2A is an isometric view of a Concentrated Photovoltaic (CPV) panel comprising an array of solar concentrator apparatuses;

FIG. 2B is a cross sectional view of a portion of the CPV panel;

FIG. 3 is an isometric view of a refracting component for use in a solar concentrator apparatus;

FIG. 4 is an isometric view of a reflecting component for use in a solar concentrator apparatus;

FIG. 5 is a top view of an electrical circuit for use in a CPV panel;

FIG. 6 is a top view of a CPV panel;

FIG. 7 is a cross-sectional view of a solar concentrator; and

FIG. 8 is an isometric view of a Concentrated Photovoltaic (CPV) panel comprising an array of solar concentrator apparatuses.

### DETAILED DESCRIPTION

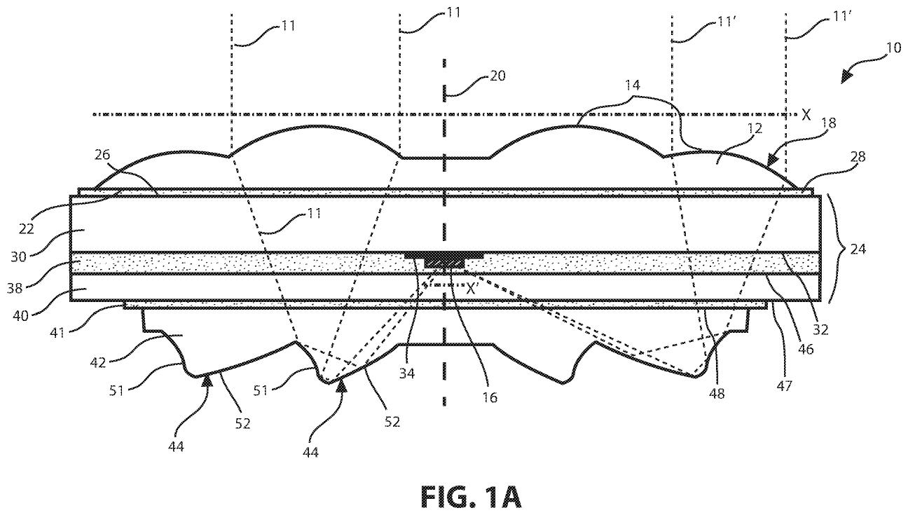

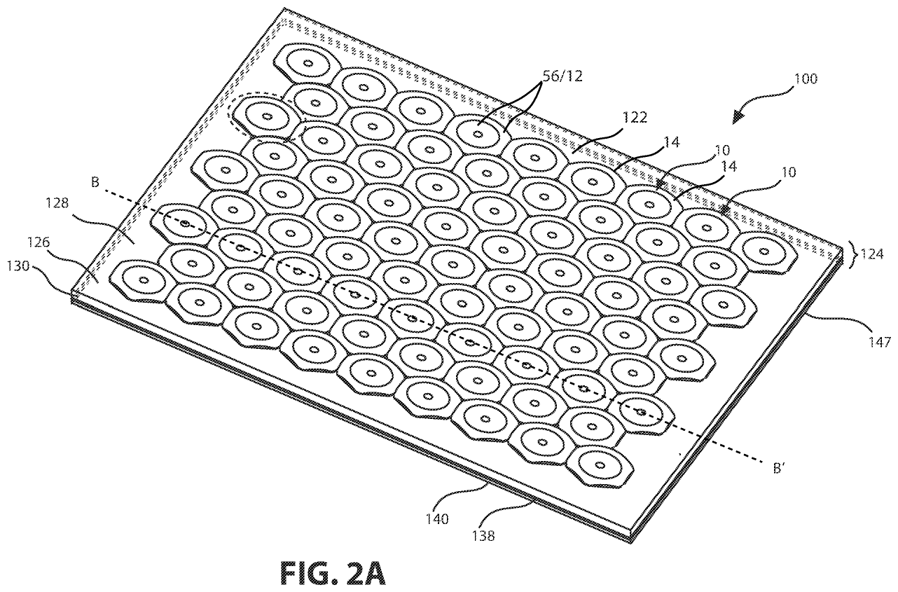

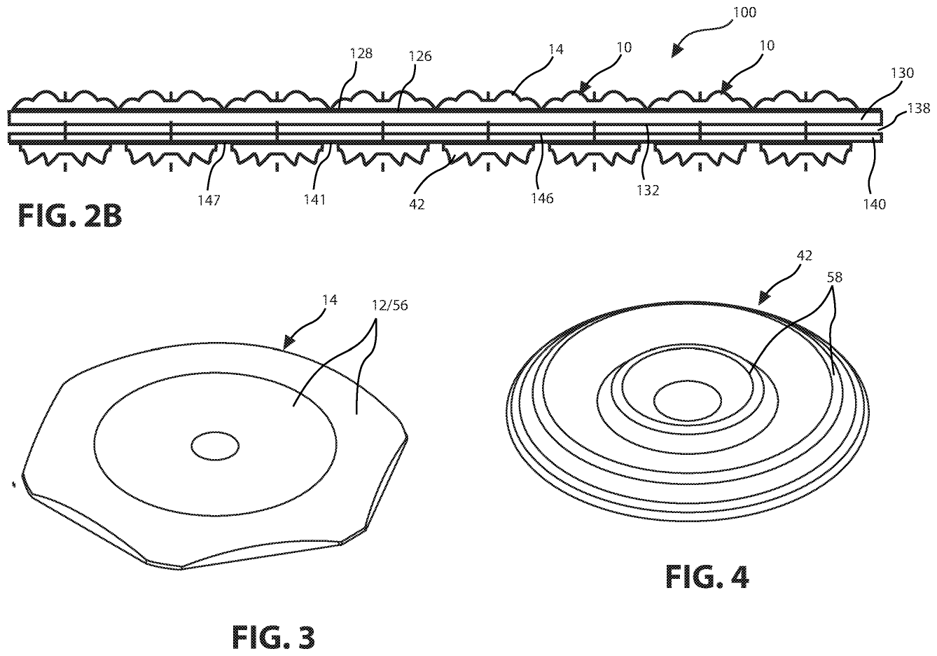

For a better understanding of various features of the present technology, reference is made to the following description which is accompanied by FIGS. 1A to 8.

FIG. 1A is a cross sectional view of an embodiment of a solar concentrator apparatus 10, for concentrating light 11 over a surface area (X in cross section), to a solar energy collector 16 of substantially smaller surface area (X′ in cross section). Specifically, FIG. 1A shows cross section A-A′ of FIG. 1B.

The solar concentrator apparatus 10 is made primarily of optically transparent components designed and positioned to transmit, refract and reflect light 11 (or in practical cases, solar light) to the solar energy collector 16, which may be a photovoltaic device, such as a high efficiency photovoltaic cell, such as a multi-junction solar cell. For example, the solar energy collector 16 can be a GaInP/GaInAs/Ge III-V triple-junction solar cell for generating electric energy from light.

The solar concentrator apparatus 10 comprises a substantially planar refracting component 12, having two plano-convex refracting elements 14 or lenses for focusing light. Light rays 11 and 11′ are illustrated in the Figures to included to indicated sample optical paths through the apparatus 10. The refracting component 12 comprises a flat surface 22, comprising the planar portion of each plano-convex refracting element 14. Via the flat surface 22, the refracting component 12 can be optically and mechanically bonded to another flat surface (namely, to a first bonding surface 26, described in further detail below). Furthermore, the refracting component 12 is made of an optically transparent material, which in some embodiments may be an injection molded polymer such as PMMA (Poly(methyl methacrylate)). A person skilled in the art would understand that many alternative configurations of the refracting component 12 would fall under the scope of the present technology. In some exemplary embodiments the refracting component 12 may have any desirable number of refracting elements 14. In some other exemplary embodiments the refracting elements 14 may vary in shape, such that the refracting elements 14 of a given refracting component 12 may have any desired focal length to suit the design and functional needs of the solar concentrator apparatus 10.

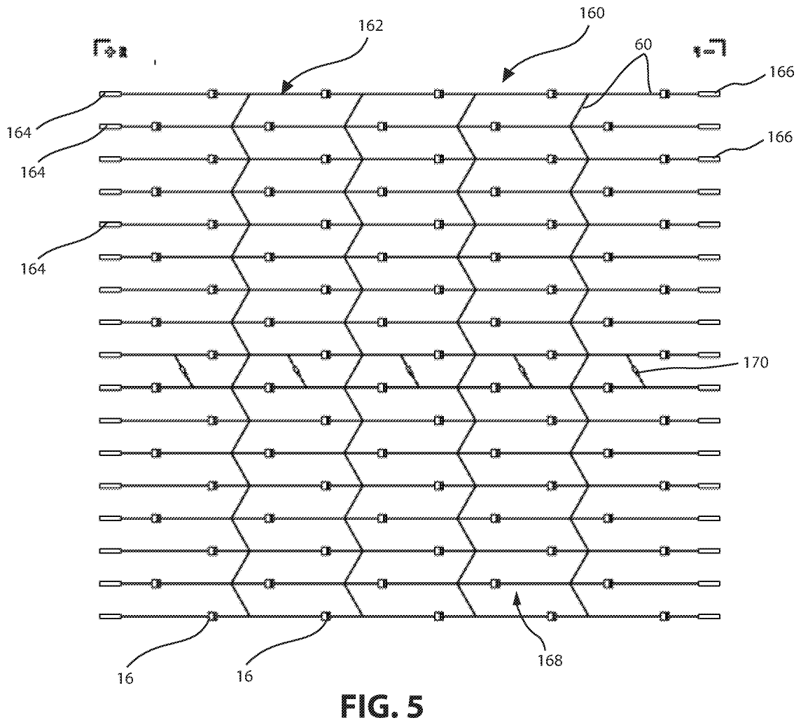

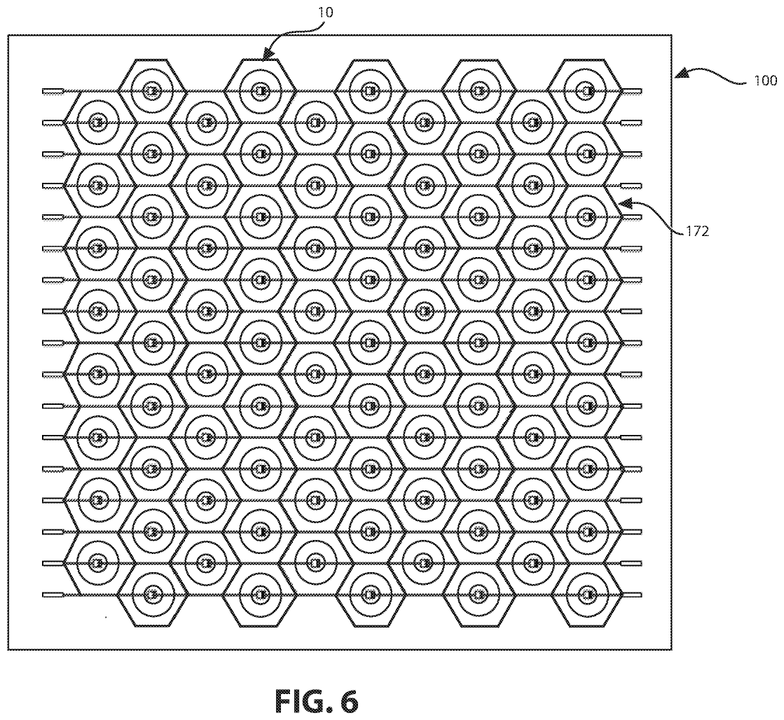

The solar concentrator 10 further comprises a receiving layer 24 comprising a first transparent sheet 30, an encapsulating layer 38, a second transparent sheet 40, electrical conductors 60 (shown in FIGS. 5 and 6) and the solar energy collector 16. The electrical conductors 60, the plurality of solar energy collectors 16 and the encapsulating layer 38 are sandwiched between the first transparent sheet 30 and the second transparent sheet 40. The first transparent sheet 30 and the second transparent sheet 40 are planar, optically transparent sheets of rigid material such as glass or a polymer. The electrical conductors 60 and the solar energy collector 16 are bonded mechanically to the first transparent sheet 30, such that electrical conductors 60 conduct electricity and heat away from the solar energy collector 16; and the first transparent sheet 30, being in direct contact with the electrical conductors 60 and the solar energy collectors 16, aids in dissipating heat away from the solar energy collector 16. Furthermore, an electrical circuit comprising the electrical conductors 60 and the solar energy collector 16 is positioned to substantially avoid the optical path of light 11 being transmitted within the solar concentrator 10.

The first transparent sheet 30 is adjacent to the refracting component 12 and is optically and mechanically connected thereto from a first bonding surface 26 of the first transparent sheet 30.

An elastomeric first bonding layer 28 is positioned between the flat surface 22 of the refracting component 12 and the first bonding surface 26 of the first transparent sheet 30. The first bonding layer 28 may be composed of any suitable optical adhesive, but preferably it is a light-transmissive elastomeric polymer with adhesive properties such as silicone, which can be applied to either the flat surface 22 or to the first bonding surface 26. The two surfaces (22, 26) may then be brought together to form an optical and mechanical bond between the refracting component 12 and the receiving layer 24. In some embodiments, a suitable material that can make up the first bonding layer 28 can be applied evenly, in liquid form, to the first bonding surface 26 or to the flat surface 22. This material may then cure or dry to form the first bonding layer 28, such that it creates a solid mechanical bond with each one of the components, holding them together firmly, yet compliantly where the material is elastomeric.

An elastomeric first bonding layer 28 is beneficial when the materials of the refracting component 12 and the first transparent sheet 30 have different coefficients of thermal expansion, since it allows the different components to expand or contract at different rates without breaking or impairing the bond between them. In an exemplary embodiment, where the first transparent sheet 30 is made of a material with a lower coefficient of thermal expansion than the refracting component 12, and the first bonding layer 28 is made of an elastomeric adhesive such as silicone, if the solar energy collector 10 is exposed to heat, the refracting component 12 will expand at a faster rate than the first transparent sheet 30, and the first bonding layer 28 will comply to the difference in thermal expansion, by stretching or expanding in response to the expansion of the refracting component 12 and the first transparent sheet 30, maintaining the optical and mechanical bond between the two components.

In the embodiment of FIG. 1A, the first transparent sheet 30 and the second transparent sheet 40 provide rigidity to the solar concentrator apparatus 10. The first transparent sheet 30 supports the electrical conductors 60 and the solar energy collector 16, and aids in dissipating heat away from the solar energy collector 16. The thickness and material of the first transparent sheet 30 must therefore be chosen taking into account the size of the solar energy collector 16 and the amount of heat the solar energy collector 16 can produce. The electrical conductors 60 and the solar energy collector 16 are attached to a second bonding surface 32 of the first transparent sheet 30, which is spaced apart and parallel to the first bonding surface 26.

The first transparent sheet 30 can be thicker than the second transparent sheet 40, since the solar energy collector 16 is attached thereto, and therefore it must withstand the heat produced by the solar energy collector 16. In some embodiments the solar energy collector 16 may include a photovoltaic cell 34 with an electrically insulating substrate 36, or in some embodiments the photovoltaic cell 34 can be bonded directly onto the second bonding surface 32 and connected do the electrical circuit.

The second transparent sheet 40 comprises a third bonding surface 46 and a fourth bonding surface 47, both bonding surfaces (46, 47) being flat and parallel to one another. The first transparent sheet 30 and the second transparent sheet 40 can be sheets of glass or any suitable rigid, light-transmissive material that can provide rigidity to the solar concentrator apparatus 10, provide protection to the solar energy collectors 16 and electrical conductors 60, and allow heat to dissipate without damaging the solar concentrator apparatus 10. The encapsulating layer 38 occupies the space between the second bonding surface 32 of the first transparent sheet 30 and the third bonding surface 46 of the second transparent sheet 40. The encapsulating layer 38 protects the solar energy collector 16 and creates an optical bond between the first transparent sheet 30 and the second transparent sheet 40. If the refractive indices of the encapsulating layer 38, the first transparent sheet 30, and the second transparent sheet 40 are sufficiently matched, the overall efficiency of the solar energy collector 10 may be increased, since index matching significantly reduces backscattering, and allows light 11 to travel within the receiving layer 24 with negligible angles of refraction. The encapsulating layer 38 can be any suitable optically transparent material including a gas such as air, an optical immersion liquid, an optical gel, or any index matched, light transmissive material or polymer such as silicone. In practical embodiments such as that of FIG. 1A, the material of the encapsulating layer 38 has optical and adhesive properties.

The solar concentration apparatus 10 further comprises a substantially planar reflecting component 42, adjacent to the receiving layer 24, and optically and mechanically connected thereto. The reflecting component 42 comprises two reflecting elements 44, wherein each reflecting element 44 of the reflecting component 42 corresponds to and works in conjunction with a refracting element 14 of the refracting component 12. The reflecting component 42 comprises a flat surface 48, so that it can be optically and mechanically bonded to the fourth bonding surface 47 of the second transparent sheet 40. Furthermore, the reflecting component 42 is made of an optically transparent material, which may be an injection molded polymer such as PMMA, or any other suitable transparent material, such as polymers or glass.

An elastomeric second bonding layer 41 is positioned between the flat surface 48 of the reflecting component 42 and the fourth bonding surface 47 of the second transparent sheet 40. The second bonding layer 41 may be composed of any suitable optical adhesive, but preferably it is a light-transmissive elastomeric polymer with adhesive properties such as silicone, which can be applied to either the flat surface 48 or to the fourth bonding surface 47. The two surfaces (46, 48) may then be brought together to form an optical and mechanical bond between the reflecting component 42 and the receiving layer 24. In some embodiments, a suitable material that can make up the second bonding layer 41 can be applied evenly, in liquid form, to the fourth bonding surface 47 or to the flat surface 48. This material may then cure or dry to form the second bonding layer 41, such that it creates a solid mechanical bond with each one of the components, holding them together firmly, yet compliantly where the material is elastomeric.

An elastomeric second bonding layer 41 is beneficial when the materials of the reflecting component 42 and the second transparent sheet 40 have different coefficients of thermal expansion, since it allows the different components to expand or contract at different rates without breaking or impairing the bond between them. In an exemplary embodiment, where the second transparent sheet 40 is made of a material with a lower coefficient of thermal expansion than the reflecting component 42, and the second bonding layer 41 is made of an elastomeric adhesive such as silicone, if the solar energy collector 10 is exposed to heat, the reflecting component 42 will expand at a faster rate than the second transparent sheet 40, and the second bonding layer 41 will comply to the difference in thermal expansion, by stretching or expanding in response to the expansion of the reflecting component 42 and the second transparent sheet 40, maintaining the optical and mechanical bond between the two components.

A person skilled in the art would understand that many alternative configurations of the reflecting component 42 would fall under the scope of the present technology. In some exemplary embodiments the reflecting component 42 may have any desirable number of reflecting elements 44 to match the number of refracting elements 12. In some other exemplary embodiments the reflecting elements 44 may vary in shape, such that the reflecting elements 44 of a given reflecting component 42 may have any desired shape to suit the design and functional needs of the solar concentrator apparatus 10.

In the embodiment of FIG. 1A, each reflecting element 44 of the reflecting component 42 comprises a first reflector 51, wherein each first reflector 51 is associated directly with one of the refracting elements 14 of the refracting component 12. Each reflecting element 44 further comprises a second reflector 52 adjacent to the first reflector 51, wherein each second reflector 52 is associated directly with the first reflector 51 of the same reflecting element 44. Therefore, for each pair of first and second reflectors (51 and 52 respectively), there is an associated refracting element 14.

The refracting elements 14 are positioned to receive input light 11 and to focus the light 11 by refraction, such that the focused light 11 travels through the bodies of the refracting element 12, the receiving layer 24, and the reflecting element 42 towards an associated first reflector 51, which, in turn, reflects the light 11 towards the associated second reflector 52 which is positioned to receive light from its associated first reflecting element 44, and reflect the light 11 towards the solar energy collector 16 for converting the light 11 into electrical energy.

Although in the embodiment described above, the refracting component 12 comprises refracting elements 14 that are generally ring-shaped lenses arranged in a concentric manner, in other embodiments, the refracting elements 14 may have a different shape and/or configuration.

Although the cross sectional embodiment of FIG. 1A can be linearly extruded such that the refracting elements 14 are linearly parallel and adjacent to one another, and the reflecting elements 44 are linearly parallel and adjacent to one another, extending from a central plane 20, higher efficiency can be achieved if each solar concentrator apparatus 10 is formed by revolving the cross sectional embodiment of FIG. 1A about an optical axis 20, running through the middle of each solar concentrator apparatus 10, as depicted in FIGS. 1B and 1C.

In embodiments where the solar concentrator 10 is generally symmetrical about optical axis 20 (revolved embodiments), the refracting elements 14 are concentric and adjacent plano-convex refracting rings 56 or lenses revolved around the optical axis 20 as shown in FIG. 1B. In such embodiments the reflecting elements 44 are concentric and adjacent plano-convex reflecting rings 58. In embodiments where there are greater or fewer than two refracting rings 56, there should be the same number of reflecting rings 58 in order for the solar concentrator apparatus 10 to work effectively. Revolved embodiments can achieve much higher rates of concentration than linearly extruded embodiments.

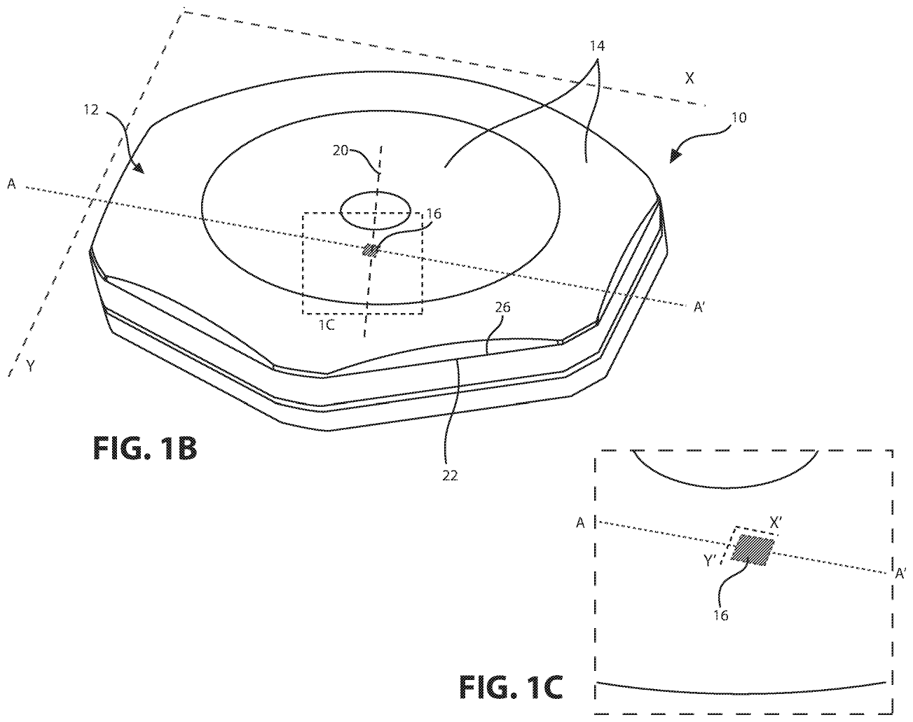

A single solar concentrator apparatus 10 as described above and shown in FIG. 1 is useful for concentrating light onto a solar energy collector 16 (for conversion into electrical energy). However, greater benefits can be achieved from tiling several solar concentrator apparatuses 10 to form a concentrated photovoltaic (CPV) panel 100 as shown in FIG. 2A.

An exemplary CPV panel 100 can have a single receiving layer 124, comprising one or more solar concentrator apparatuses 10, the receiving layer 124 providing structure to the array of solar concentrators 10.

FIG. 2A is a top perspective view of an embodiment of a CPV panel 100. The CPV panel 100 has a receiving layer 124, comprising an array of solar energy collectors 16, wherein the single receiving layer 124 provides structure to an array of solar concentrators 10. FIG. 2B shows cross section B-B′ of FIG. 2A.

The receiving layer comprises a first transparent sheet 130, an encapsulating layer 138, a second transparent sheet 140, and a patterned electrical circuit 160 (shown in FIGS. 5 and 6) comprising an array of solar energy collectors 16 connected to a plurality of electrical conductors 60. The patterned electrical circuit 160 and the encapsulating layer 138 are sandwiched between the first transparent sheet 130 and the second transparent sheet 140. The first transparent sheet 130 and the second transparent sheet 140 are planar, optically transparent sheets of rigid material such as glass or a polymer. The electrical circuit 160 is bonded mechanically to the first transparent sheet 130, such that the electrical conductors 60 conduct electricity and heat away from the solar energy collectors 16; and the first transparent sheet 130, being in direct contact with the patterned electrical circuit 160, aids in dissipating heat away from the solar energy collectors 16. Furthermore, the patterned electrical circuit 160 is positioned to substantially avoid the optical path of light 11 being transmitted within the CPV panel 100.

The plurality of refracting components 12 of each of the solar concentrators 10 are optically and mechanically bonded to a first bonding surface 122 of the first transparent sheet 130 by means of a first bonding layer 128. Similar to the embodiment of FIG. 1, the first bonding layer 128 (28 in FIG. 1) may be an elastomeric adhesive that is light-transmissive, and, in the embodiment of FIGS. 2A and 2B, it can be applied to the first bonding surface 126 to create a bond with the plurality of refracting components 12, which are attached from their flat surface 22. It is possible to have the entire array of refracting components 12 formed as a single solid sheet of PMMA or any other suitable material, wherein the sheet comprising the plurality of refracting components 12 is bonded to the first bonding surface 126; or alternatively it is possible to form each of the refracting components 12 individually out of PMMA or any other suitable material and bond them separately to the first bonding surface 126 by means of the first bonding layer 128.

An elastomeric first bonding layer 128 is beneficial when the materials of the refracting components 12 and the first transparent sheet 30 have different coefficients of thermal expansion, since it allows the different components to expand or contract at different rates without breaking or impairing the bond between them. In an exemplary embodiment, where the first transparent sheet 130 is made of a material with a lower coefficient of thermal expansion than the refracting components 12, and the first bonding layer 128 is made of an elastomeric adhesive such as silicone, if the CPV panel 100 is exposed to heat, the refracting components 12 will expand at a faster rate than the first transparent sheet 130, and the first bonding layer 128 will comply to the difference in thermal expansion, by stretching or expanding in response to the expansion of the refracting components 12 and the first transparent sheet 130, maintaining the optical and mechanical bond between the two components.

In the embodiment of FIGS. 2A and 2B, the first transparent sheet 130 and the second transparent sheet 140 provide rigidity to the CPV panel 100. However, while the second transparent sheet 140 is merely a structural component, the first transparent sheet 130 supports the patterned electrical circuit 160 and the plurality of solar energy collectors 16, and aids in dissipating heat away from the solar energy collectors 16. The thickness and material of the first transparent sheet 130 must therefore be chosen taking into account the size of the solar energy collectors 16 and the amount of heat the solar energy collectors 16 can produce. The patterned electrical circuit 160 and the solar energy collectors 16 are attached to a second bonding surface 132 of the first transparent sheet 130, which is spaced apart and parallel to the first bonding surface 126.

The second transparent sheet 140 comprises a third bonding surface 146 and a fourth bonding surface 147, both bonding surfaces (146, 147) being flat and parallel to one another. The first transparent sheet 130 and the second transparent sheet 140 can be sheets of glass or any suitable rigid, light-transmissive material to provide rigidity to the CPV panel 100, to provide protection to the plurality of solar energy collectors 16 and electrical conductor pattern 160, and to allow heat to dissipate without damaging the CPV panel 100. The encapsulating layer 138 occupies the space between the second bonding surface 132 of the first transparent sheet 130 and the third bonding surface 146 of the second transparent sheet 140. The encapsulating layer 138 protects the solar energy collectors 16 and creates an optical bond between the first transparent sheet 130 and the second transparent sheet 140, and if the refractive indices are sufficiently matched, it provides a higher overall efficiency to the CPV panel 100, since index matching significantly reduces backscattering, and allows light 11 to travel within the receiving layer 124 with negligible angles of refraction. The encapsulating layer 138 can be any suitable optically transparent material including a gas such as air, an optical immersion liquid, an optical gel, or any index matched, light transmissive material or polymer such as silicone. In practical embodiments such as that depicted in FIGS. 2A and 2B, the material of the encapsulating layer 138 has optical and adhesive properties. For example, an index matched polymeric material such as silicone can be used to make up the encapsulating layer 138, wherein the index of refraction of the material forming the encapsulating layer 138 is matched to the index of refraction of the first transparent sheet 130 and the second transparent sheet 140, and such that the encapsulating layer 138 can hold the first transparent sheet 130 and the second transparent sheet 140 together in an optical and mechanical bond.

The plurality of reflecting components 42 of each of the solar concentrators 10 are optically and mechanically bonded to a fourth bonding surface 147 of the second transparent sheet 140 by means of a second bonding layer 141. Similar to the embodiment of FIG. 1, the second bonding layer 141 (41 in FIG. 1) may be an elastomeric adhesive that is light-transmissive, and, in the embodiment of FIGS. 2A and 2B, it can be applied to the fourth bonding surface 147, to create a bond with the plurality of reflecting components 42 of the array, which are attached from their flat surface 48. It is possible to form the entire array of reflecting components 42 as a single solid sheet of PMMA or any other suitable material, wherein the sheet comprising the plurality of reflecting components 42 is bonded to the fourth bonding surface 147; or alternatively it is possible to form each of the reflecting components 42 individually out of PMMA or any other suitable material and bond them separately to the fourth surface 147 by means of the second bonding layer 141.

An elastomeric second bonding layer 141 is beneficial when the materials of the reflecting components 42 and the second transparent sheet 140 have different coefficients of thermal expansion, since it allows the different components to expand or contract at different rates without breaking or impairing the bond between them. In an exemplary embodiment, where the second transparent sheet 140 is made of a material with a lower coefficient of thermal expansion than the reflecting components 42, and the fourth bonding layer 147 is made of an elastomeric adhesive such as silicone, if the CPV panel 100 is exposed to heat, the reflecting components 42 will expand at a faster rate than the second transparent sheet 140, and the second bonding layer 141 will comply to the difference in thermal expansion, by stretching or expanding in response to the expansion of the reflecting components 42 and the second transparent sheet 140, maintaining the optical and mechanical bond between the two components.

The electrical circuit 160 can include a conductor grid 162 made of an electrically and thermally conductive material, which can be fabricated as a single unit with connection points for each of the solar energy collectors 16. The conductor grid 162 further comprises a plurality of positive contacts 164 and a plurality of negative contacts 166, and a plurality of electrical conductors 60 for interconnecting solar energy collectors 16. The positive contacts 164 can all be connected in parallel by a first strip of conductive material (not shown) such as a metal strip, and the negative contacts 166 can also be connected in parallel by a second strip of conductive material (not shown). The first and second strips of conductive material form two leads, one positive and one negative, which can be connected to a load for extraction of current, such as a grid-connected inverter.

The conductor grid 162 can be disposed against the second bonding surface 132 of the first transparent sheet 130 and bonded thereto by means of an adhesive glue or any type of suitable adhesive or bonding process. The conductor grid 162 may also be fabricated directly on the first transparent sheet 130 by metallization. The solar energy collectors 16 can be bonded to conductor grid 162 and to the second bonding surface 132 with a conductive epoxy, which can allow attachment to first transparent sheet 130 and electrical connection to the conductor grid 162 in a single step during assembly. Alternatively, positive and negative contacts of each solar energy collector 16 can be electrically attached or soldered to the electrical conductors 60 of the conductor grid 162. In some embodiments, one of the positive or negative contacts of each solar energy collector 16 can be soldered to or bonded with a conductive epoxy to the electrical conductors 60 while the other contact is electrically connected to the conductor grid 162 by wire bonding, spring clipping or any other means known in the art. The electrical circuit 160 is and all components thereof are generally encapsulated by the material of the encapsulating layer 138.

In some embodiments the conductor grid 162 can be a pattern of stamped copper foil or any other conductive material. The electrical conductors 60 are positioned for interconnecting solar energy collectors 16, wherein solar energy collectors 16 of each row are connected in series, and solar energy collectors 16 of each column are connected in parallel. The embodiments shown in FIGS. 2A, 2B, 5 and 6, comprise eighty five (85) solar concentrator apparatuses 10, however, the conductor grid 162 can interconnect an array of any number of solar energy collectors 16 (or from a macroscopic perspective the conductor grid 162 can interconnect any number of solar concentrator apparatuses 10 as seen in FIG. 6), and the solar energy collectors 16 of the array can be arranged to form any desirable pattern. The conductor grid 162 is made of an electrically conductive metal such as copper, silver, or any suitable electrically conductive material. The conductor grid 162 can be applied onto the second surface 132 of the first transparent sheet 130 by a metallization process such as sputtering, galvanizing or screen printing a thick film. Alternatively, conductors, such as wires, ribbons and/or foils, can be attached to the first transparent sheet 130 using a bonding agent such as epoxy and/or by soldering the conductors to metallizations on the first transparent sheet (e.g., metallized dots not shown).

The conductor grid 162 also serves as a heat spreader by dissipating the heat generated by the solar energy collector 16 to mainly the first transparent sheet 130, as well as to the encapsulating layer 138 and the second transparent sheet 140. It is contemplated that heat generated by the collector 16 could be dissipated through different means, depending on the embodiment.

The solar concentrators 10 of the present technology most efficiently concentrate light 11 when solar concentrators 10 are positioned to receive light 11 impinging thereon at an angle normal to a plane X, Y defined by the first flat surface 30, as shown in FIG. 1B. The CPV panel 100 can be made to have dimensions similar to those of a conventional non-concentrating photovoltaic panel, and thereby serve as a replacement product in suitable deployments (e.g., may replace conventional photovoltaic panels mounted on a tracker).

Non-limiting examples of light transmissive materials that may be used to form the refracting components 12, the first transparent sheet 30, 130, the second transparent sheet 40, 140, and the reflecting components 42 include glass, light transmissive polymeric materials such as rigid, injection molded poly(methyl methacrylate) (PMMA), polymethyl methacrylimide (PMMI), polycarbonates, cyclo olefin polymers (COP), cyclo olefin copolymers (COC), polytetrafluoroethylene (PTFE), or a combination of these materials. For example, the first transparent sheet 30, 130 and the second transparent sheet 40, 140 can be sheets of glass, and the refracting components 12 and the reflecting components 42 can be made of PMMA. Alternatively, the refracting components 12 and the reflecting components 42 can be made of a silicone rubber. Attachment of each of the refracting components 12 and the reflecting components 42 to the receiving layer 24, 124 can be achieved by optically bonding the refracting components 12 and the reflecting components 42 to the receiving layer 24, 124 with an optical bonding agent, laser welding (where all components are made of polymers) or any other means known in the art. As an example, if the refracting components 12 and the reflecting components 42 are made of a polymeric material, they can be optically bonded to glass surfaces of the first transparent sheet 30, 130 and second transparent sheet 40, 140 using an optical adhesive such as a silicone. Alternatively, the refracting components 12 and the reflecting components 42 can be 3D printed directly on the glass surfaces of the first transparent sheet 30, 130 and second transparent sheet 40, 140, or the surfaces of the receiving layer 24 can be coated with a polymer, such as a silicone rubber, and the polymeric refracting components 12 and reflecting components 42 can be 3D printed thereon.

Although the embodiments of the present technology show refracting components 12 cropped into the shape of a hexagon to eliminate dead space, in other embodiments the refracting components 12 can be circular or cropped into any tileable shape such as a square. Although the illustrated embodiments shows circular reflecting components 42, in other embodiments the reflecting components 42 can be cropped into any tileable shape such as a hexagon or a square.

According to the present technology, and as shown in FIG. 5, a plurality of bypass diodes 170 can be included in the electrical circuit 160. The electrical circuit 130 can be viewed as including a plurality of serially connected strings 168, each string 168 comprising a column of cells connected in parallel, wherein a bypass diode 170 is connected in parallel with the column of cells and is positioned near the center of each string. The bypass diodes 170 improve the performance of the CPV panel 100 in the event of shading of one or more solar concentrators 10 by allowing current to flow unimpeded past the solar energy collectors of shaded, dirty or deficient solar concentrators 10. In other embodiments, each solar energy collector 16 may alternatively include a bypass diode to improve the performance of the panel in the event of shading of one or more solar concentrators 10, or when differences in optical efficiency exist between the solar concentrators 10 or the solar energy collectors 16.

Although embodiments have been described above with reference to the accompanying drawings, those of skill in the art will appreciate that variations and modifications may be made without departing from the scope thereof as defined by the appended claims.

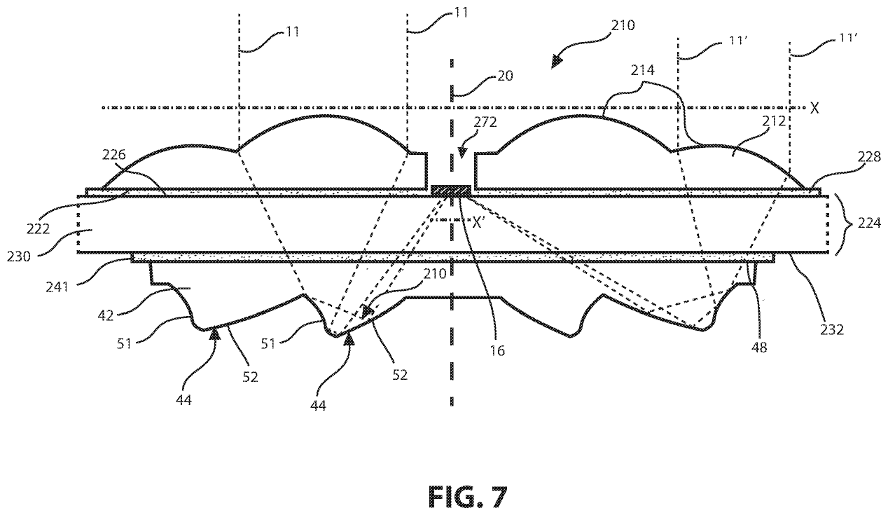

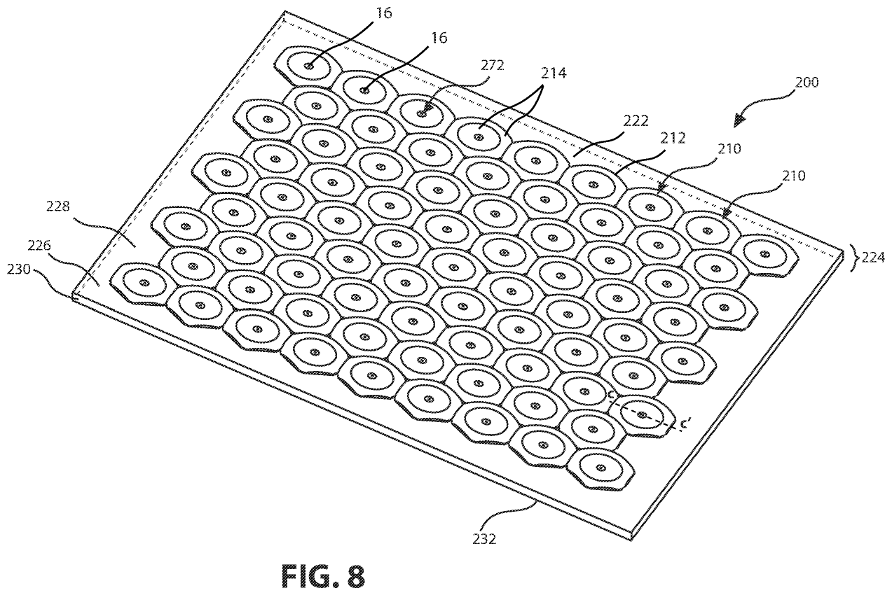

Another embodiment of a solar concentrator according to the present technology is shown in FIG. 7, where a solar concentrator apparatus 210 comprises a modified refracting component 212, a single sheet receiving layer 224 and the reflecting component 42 (same as described above). FIG. 7 is a cross sectional view of the solar concentrator apparatus 210, for concentrating light 11 over a surface area (X in cross section), to the solar energy collector 16 of substantially smaller surface area (X′ in cross section). Specifically, FIG. 7 shows cross section C-C′ of FIG. 8.

The refracting component 212 is a substantially planar refracting component 212, having two plano-convex refracting elements 214 or lenses for focusing light 11. The refracting component 212 comprises a flat surface 222, comprising the planar portion of each plano-convex refracting element 214. Via the flat surface 222, the refracting component 212 can be optically and mechanically bonded to another flat surface (namely, to a first bonding surface 226, described in further detail below). The refracting component 212 defines a hole 272 at its center, such that the material of the refracting component 212 does not directly enter in contact with the solar energy collector 16, avoiding heat damage to the refracting component 212. Furthermore, the refracting component 212 is made of an optically transparent material, which in some embodiments may be an injection molded polymer such as PMMA (Poly(methyl methacrylate)).

The refracting elements 214 are positioned such that they refract light (for instance the rays 11, 11′) impinging on them, directly towards the reflecting component 42. The reflecting elements 44 then direct the light 11, 11′ directly toward the solar energy collector 16. The solar energy collector 16 receives light reflected from each of the reflecting elements 44 immediately subsequent reflection by the second reflecting surface 52.

A person skilled in the art would understand that many alternative configurations of the refracting component 212 would fall under the scope of the present technology. In some exemplary embodiments the refracting component 212 may have any desirable number of refracting elements 214. In some other exemplary embodiments the refracting elements 214 may vary in shape, such that the refracting elements 214 of a given refracting component 212 may have any desired focal length to suit the design and functional needs of the solar concentrator apparatus 210.

The solar concentrator 210 further comprises a receiving layer 224 comprising a rigid transparent sheet 230, electrical conductors 60 (shown in FIGS. 5 and 6) and a solar energy collector 16. The electrical conductors 60 are sandwiched between the rigid transparent sheet 230 and the refracting component 212. The rigid transparent sheet 230 is a planar, optically transparent sheet of rigid material such as glass or a polymer. The electrical conductors 60 and the solar energy collector 16 are bonded mechanically to the rigid transparent sheet 230, such that electrical conductors 60 conduct electricity and heat away from the solar energy collector 16; and the rigid transparent sheet 230, being in direct contact with the electrical conductors 60 and the solar energy collectors 16, aids in dissipating heat away from the solar energy collector 16. Furthermore, an electrical circuit comprising the electrical conductors 60 and the solar energy collector 16 is positioned to substantially avoid the optical path of light being transmitted within the solar concentrator, such as the paths followed by light rays 11, 11′. The light rays 11, 11′ will generally pass between portions of the electrical conductors, thereby aiding in minimizing optical effects from the electrical circuit.

The rigid transparent sheet 230 is adjacent to the refracting component 212 and is optically and mechanically connected thereto from a first bonding surface 226 of the first transparent sheet 230.

An elastomeric first bonding layer 228 is positioned between the flat surface 222 of the refracting component 212 and the first bonding surface 226 (comprising electrical conductors 60) of the rigid transparent sheet 230. The first bonding layer 228 may be composed of any suitable optical adhesive, but preferably it is a light-transmissive elastomeric polymer with adhesive properties such as silicone, which can be applied to either the flat surface 222 or to the first bonding surface 226. The two surfaces (222, 226) may then be brought together to form an optical and mechanical bond between the refracting component 212 and the receiving layer 224. The first bonding layer 228 also acts as an encapsulant for the electrical conductors 60 and the solar energy collector 16. In some embodiments, a suitable material that can make up the first bonding layer 228 can be applied evenly, in liquid form, to the first bonding surface 226 or to the flat surface 222. This material may then cure or dry to form the first bonding layer 228, such that it creates a solid mechanical bond with each one of the components, holding them together firmly, yet compliantly where the material is elastomeric.

The rigid transparent sheet 230 must be thick enough to withstand and dissipate the heat produced by the solar energy collector 16, such that the heat does not damage any of the other components of the solar concentrator apparatus 210. In some embodiments the solar energy collector 16 may include a photovoltaic cell 34 with an electrically insulating substrate 36 (as shown in the embodiment of FIG. 1A), or in some embodiments the photovoltaic cell 34 can be bonded directly onto the second bonding surface 32 and connected do the electrical circuit.

The solar concentration apparatus 210 further comprises a substantially planar reflecting component 42, as described in previous embodiments. The reflecting component is adjacent to the receiving layer 224, and optically and mechanically connected thereto by means of an elastomeric second bonding layer 241 positioned between the flat surface 48 of the reflecting component 42 and the second bonding surface 232 of the rigid transparent sheet 230. The second bonding layer 241 may be composed of any suitable optical adhesive, but preferably it is a light-transmissive elastomeric polymer with adhesive properties such as silicone, which can be applied to either the flat surface 48 or to the second bonding surface 232. The two surfaces (232, 48) may then be brought together to form an optical and mechanical bond between the reflecting component 42 and the receiving layer 224. In some embodiments, a suitable material that can make up the second bonding layer 241 can be applied evenly, in liquid form, to the second bonding surface 232 or to the flat surface 48. This material may then cure or dry to form the second bonding layer 241, such that it creates a solid mechanical bond with each one of the components, holding them together firmly, yet compliantly where the material is elastomeric.

FIG. 8 is a top perspective view of an embodiment of a CPV panel 200. The CPV panel 200 has a receiving layer 224, wherein the single receiving layer 224 provides structure to an array of solar concentrators 210.

The receiving layer comprises a rigid transparent sheet 230, a first bonding layer 228, a patterned electrical circuit 160 (shown in FIGS. 5 and 6) comprising an array of solar energy collectors 16 connected to a plurality of electrical conductors 60. The patterned electrical circuit 160 and the first bonding layer 228 are sandwiched between the rigid transparent sheet 230 and a plurality of refracting components 212. The rigid transparent sheet 230 is a planar, optically transparent sheet of rigid material such as glass or a polymer. The electrical circuit 160 is bonded mechanically to the rigid transparent sheet 230, such that the electrical conductors 60 conduct electricity and heat away from the solar energy collectors 16; and the rigid transparent sheet 230, being in direct contact with the patterned electrical circuit 160, aids in dissipating heat away from the solar energy collectors 16. Furthermore, the patterned electrical circuit 160 is positioned to substantially avoid the optical path of light 11 being transmitted within the CPV panel 200.

The plurality of refracting components 212 of each of the solar concentrators 210 are optically and mechanically bonded to a first bonding surface 222 of the rigid transparent sheet 230 by means of a first bonding layer 228. As described above in relation to FIGS. 1 and 7, the first bonding layer 228 may be an elastomeric adhesive that is light-transmissive, and, in the embodiment of FIG. 8, it can be applied to the first bonding surface 226 to create a bond with the plurality of refracting components 212, which are attached from their flat surface 222. It is possible to have the entire array of refracting components 212 formed as a single solid sheet of PMMA or any other suitable material, wherein the sheet comprising the plurality of refracting components 212 is bonded to the first bonding surface 226; or alternatively it is possible to form each of the refracting components 212 individually out of PMMA or any other suitable material and bond them separately to the first bonding surface 226 by means of the first bonding layer 228.

The rigid transparent sheet 230 comprises a second bonding surface 232 wherein the first bonding surface 226 and the second bonding surface 232 are flat and parallel to one another. The rigid transparent sheet 230 can be a sheet of glass or any suitable rigid, light-transmissive material to provide rigidity to the CPV panel 200, to provide protection to the plurality of solar energy collectors 16 and electrical conductor pattern 160, and to allow heat to dissipate without damaging the CPV panel 200. Each of the refracting components 212 comprise a donut hole 272 at their center, such that the solar energy collectors 16 do not enter in direct contact with the material of the refracting component 212, therefore avoiding potential heat damage. The first bonding layer 228 protects the solar energy collectors 16, encapsulating the electrical circuit 160 and creating an optical bond between the rigid transparent sheet 230 and the flat surface 222. If the refractive indices of separate components are sufficiently matched, it provides a higher overall efficiency to the CPV panel 200, since index matching significantly reduces backscattering, and allows light 11 to travel within the receiving layer 224 with negligible angles of refraction.

The CPV panel 200 further comprises a plurality of substantially planar reflecting components 42, as described in previous embodiments. The reflecting components are adjacent to the receiving layer 224, and optically and mechanically connected thereto by means of an elastomeric second bonding layer 241 positioned between the flat surface 48 of the plurality of reflecting components 42 and the second bonding surface 232 of the rigid transparent sheet 230. Similar to the embodiment of FIG. 1, the second bonding layer 241 may be an elastomeric adhesive that is light-transmissive, and, in the embodiment of FIGS. 2A and 2B, it can be applied to the second bonding surface 232, to create a bond with the plurality of reflecting components 42 of the array, which are attached from their flat surface 48. It is possible to form the entire array of reflecting components 42 as a single solid sheet of PMMA or any other suitable material, wherein the sheet comprising the plurality of reflecting components 42 is bonded to the second bonding surface 232; or alternatively it is possible to form each of the reflecting components 42 individually out of PMMA or any other suitable material and bond them separately to the second bonding surface 232 by means of the second bonding layer 241.

An elastomeric second bonding layer 241 is beneficial when the materials of the reflecting components 42 and the rigid transparent sheet 230 have different coefficients of thermal expansion, since it allows the different components to expand or contract at different rates without breaking or impairing the bond between them. In an exemplary embodiment, where the rigid transparent sheet 230 is made of a material with a lower coefficient of thermal expansion than the reflecting components 42, and second bonding layer 241 is made of an elastomeric adhesive such as silicone, if the CPV panel 200 is exposed to heat, the reflecting components 42 will expand at a faster rate than the rigid transparent sheet 230, and the second bonding layer 241 will comply to the difference in thermal expansion, by stretching or expanding in response to the expansion of the reflecting components 42 and the rigid transparent sheet 230, maintaining the optical and mechanical bond between the two components.

Modifications and improvements to the above-described implementations of the present technology may become apparent to those skilled in the art. The foregoing description is intended to be exemplary rather than limiting. The scope of the present technology is therefore intended to be limited solely by the scope of the appended claims.

1. A solar concentrator apparatus comprising:
at least one refracting component, the at least one refracting component comprising a plurality of refracting elements;
a receiving layer comprising at least one solar energy collector, the receiving layer being adjacent and optically connected to the at least one refracting component;
at least one reflecting component adjacent and optically connected to the receiving layer, the at least one reflecting component being disposed on a side of the receiving layer opposite the at least one refracting component, the at least one reflecting component comprising a plurality of reflecting elements, each one of the plurality of reflecting elements being associated with a corresponding one of the plurality of refracting elements, each one of the plurality of reflecting elements comprising a first reflecting surface and a second reflecting surface;
wherein the plurality of refracting elements are positioned to refract light impinging thereon towards the at least one reflecting component, each one of the plurality of reflecting elements receiving refracted light from its corresponding one of the plurality of refracting elements, the at least one solar energy collector receiving reflected light from each one of the plurality of reflecting elements immediately subsequent reflection by the second reflecting surface.

2. The solar concentrator apparatus of claim 1, wherein the plurality of reflecting elements operate by total internal reflection.

3. The solar concentrator apparatus of claim 1, wherein each of the at least one refracting component, the receiving layer, and the at least one reflecting component includes at least one planar surface.

4. The solar concentrator apparatus of claim 1, further comprising an elastomeric layer disposed between at least a portion of the receiving layer and the at least one refracting component.

5. The solar concentrator apparatus of claim 1, further comprising an elastomeric layer disposed between the receiving layer and the at least one reflecting component.

6. The solar concentrator apparatus of claim 1, wherein for each one of the plurality of reflecting elements, the first reflecting surface is positioned to reflect light incident thereon towards the second reflecting surface, the incident light undergoing a single reflection between the corresponding one of the plurality of refracting elements and the second reflecting surface.

7. The solar concentrator apparatus of claim 1, wherein for each one of the plurality of reflecting elements, the second reflecting surface is positioned to reflect light incident thereon towards the at least one solar energy collector, the incident light undergoing a single reflection between the first reflecting surface and the at least one solar energy collector.

8. The solar concentrator apparatus of claim 1, wherein:
the receiving layer comprises a rigid transparent sheet having an electrical circuit attached thereto:
the at least one solar energy collector and the at least one refracting component are disposed on a same side of the rigid transparent sheet.

9. The solar concentrator apparatus of claim 8, wherein the at least one refracting component defines a hole at a center thereof.

10. The solar concentrator apparatus of claim 9, wherein the at least one solar energy collector is disposed within the hole.

11. The solar concentrator apparatus of claim 1, wherein the at least one solar energy collector is at least one photovoltaic cell.

12. The solar concentrator apparatus of claim 1, wherein the receiving layer comprises:
a first transparent sheet having an electrical circuit attached thereto;
a second transparent sheet operatively connected and parallel to the first transparent sheet; and
wherein:
the at least one solar energy collector is disposed between the first and second transparent sheets,
the at least one solar energy collector is at least one photovoltaic cell; and
electrical energy generated by the at least one photovoltaic cell is transmitted through the electrical circuit.

13. The solar concentrator apparatus of claim 12, wherein the receiving layer further comprises a light transmissive material disposed between the first transparent sheet and the second transparent sheet.

14. The solar concentrator apparatus of claim 13, wherein the light transmissive material acts as an adhesive between the first transparent sheet and the second transparent sheet.

15. The solar concentrator apparatus of claim 8, wherein the electrical circuit is positioned to avoid a light path within the solar concentrator apparatus.

16. A solar collector array, comprising a plurality of solar concentrator apparatuses according to claim 1.

17. The solar collector array of claim 16, wherein the solar concentrator apparatuses are arranged in a substantially hexagonal grid.

18. An array of solar concentrator apparatuses comprising:
a plurality of refracting components, each refracting component further comprising a plurality of refracting elements;
a receiving layer, the receiving layer comprising a plurality of solar energy collectors, the receiving layer being adjacent and optically connected to the plurality of refracting components;
a plurality of reflecting components, the plurality of reflecting components being adjacent and optically connected to the receiving layer, each one of the plurality of reflecting components being associated with a corresponding one of the plurality of refracting components, each one of the plurality of reflecting components comprising a plurality of reflecting elements, each one of the plurality of refracting elements being associated with a corresponding one of the plurality of reflecting elements, each of the plurality of reflecting elements comprising a first reflecting surface and a second reflecting surface;
wherein:
each one of the plurality of refracting elements is positioned to refract light impinging thereon towards the corresponding one of the plurality of reflecting elements,
for each one of the plurality of reflecting elements, the first reflecting surface reflects light towards the second reflecting surface, and
each one of the plurality of reflecting elements receives refracted light from its corresponding one of the plurality of refracting elements, the plurality of solar energy collectors receiving reflected light from each one of the plurality of reflecting elements immediately subsequent reflection by the second reflecting surface.

19. The array of solar concentrator apparatuses of claim 18, wherein the plurality of refracting components, the plurality of solar energy collectors and the plurality of reflecting components are arranged such that there is a one to one relationship between each one of the plurality of refracting components, a corresponding one of the plurality of reflecting components and a corresponding one of the plurality of solar energy collectors.
